(19) United States
(12) Patent Application Publication
(10) Pub. No.: US 2007/0000535 A1
(43) Pub. Date: Jan. 4, 2007

(54) Integrated energy conversion

(75) Inventors: Ralph M. Mesmer, Banks, OR (US); Sean Riley, Portland, OR (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/173,588

(22) Filed: Jun. 30, 2005

(51) Int. Cl. H01L 31/00

(52) U.S. Cl. 136/252

(57) ABSTRACT

Apparatus and systems, as well as methods and articles, may operate to provide direct current from a solar energy conversion device fabricated on a semiconductor substrate, and to convert the direct current to an alternating current using an electric energy conversion device, such an inverter, fabricated on the same semiconductor substrate.

### TECHNICAL FIELD

Various embodiments described herein relate to energy transport and conversion generally, including apparatus, systems, and methods used to convert solar energy.

### BACKGROUND INFORMATION

Large solar cell systems, of the type used to provide electric power in residential and commercial buildings, may be connected to the local power grid. Thus, the consumer can use energy provided by the power company at night, and during the day when solar power is insufficient for current needs. Surplus daytime energy may be fed back into the grid, obviating the need for storage. While solar cells can provide energy as direct-current (DC), power company grids typically utilize energy in the form of alternating-current (AC).

### BRIEF DESCRIPTION OF THE DRAWINGS

FIG. 1 is a block diagram of apparatus and systems according to various embodiments of the invention.

FIG. 2 is a flow diagram illustrating several methods according to various embodiments of the invention.

FIG. 3 is a block diagram of an article according to various embodiments.

### DETAILED DESCRIPTION

Electrical power fed back into the power company grid typically takes the form of a 60 Hertz sine wave; in most cases, for example, a 110 volt square wave would not be acceptable. Thus, some kind of energy conversion device, such as a solid state inverter, may be used in conjunction with solar cells and other solar energy conversion devices to provide power acceptable to the local power company. In some embodiments, an electrical energy conversion device may be formed on the same substrate as, and coupled to receive electrical energy provided by, a solar energy conversion device. For example, the electrical energy conversion device may comprise an inverter, and the solar energy conversion device may comprise a solar cell. Thus, a plurality of solar cells may be interconnected, using integrated inverters to produce alternating current for connection to the local power grid.

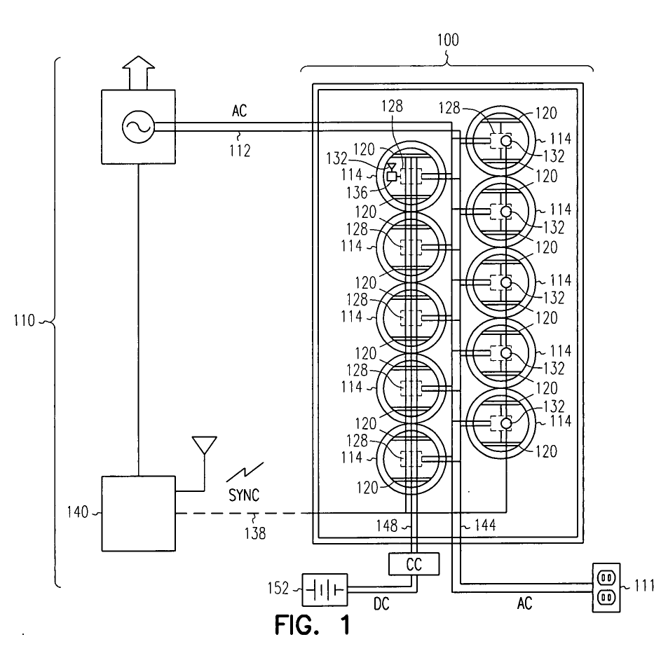

FIG. 1 is a block diagram of apparatus 100 and systems 110 according to various embodiments of the invention, each of which may operate as previously described. In some embodiments, an apparatus 100 to provide electrical power to consumers 111 and the power grid 112 may include one or more semiconductor substrates 114 with one or more solar energy conversion devices 120 (perhaps electrically coupled together) fabricated thereon. The apparatus 100 may also include one or more electrical energy conversion devices 128, fabricated on one or more of the substrates 114, so as to receive electrical energy from the solar energy conversion devices 120, either from a device 120 formed on the same semiconductor substrate 114, or from one located on another substrate 114. Each solar energy conversion device 120 may include more than one solar cell, and individual cells may include multiple P-N junctions.

The electrical energy conversion device 128 may include a number of components, such as a DC to AC conversion device, and/or a voltage step-up conversion device (e.g., a DC-DC converter, or an AC-AC converter). These may be coupled together, so as to convert the voltage provided by the solar energy conversion device to AC, and then step it up, or to step up the voltage provided, and then to convert it, for example. The electrical energy conversion device 128 may be implemented as a solid-state inverter, and/or some other type of device, such as an alternator or a generator, perhaps in the form of a MEMS (microelectromechanical system) device.

The electrical energy conversion device 128 may be fabricated in a number of ways, including directly on the semiconductor substrate 114, or as a flip-chip bonded to the semiconductor substrate 114. The semiconductor substrate 114 may include a number of materials, such as silicon, gallium, arsenide, polymers, and organic materials.

In some embodiments, it may be useful to synchronize the operation of the electric energy conversion device 128 to the output of the power grid 112. Thus, the apparatus 100 may include one or more frequency reference terminals 132 to couple to the electrical energy conversion device 128. The frequency reference terminals 132 may be used to synchronize a 60 Hertz output of the electrical energy conversion device 128 to the 60 Hertz output of the power grid 112, for example. In some embodiments, the frequency reference terminal 132 may comprise a wireless antenna, and a wireless receiver 136 may be coupled between the terminal 132 and the electrical energy conversion device 128.

Other embodiments may be realized. For example, a system 110 may include one or more apparatus 100 (perhaps electrically coupled together), described above, as well as a frequency reference 140 to couple to the electrical energy conversion device(s) 128. The frequency reference 140 (e.g., a source of a synchronizing signal, such as a power-grid synchronizing signal, including a typical 120 or 240 VAC power-line signal, or another signal derived therefrom) may be coupled to one or more of the semiconductor substrates 114 and/or the electrical energy conversion device(s) 128, using direct, switched, wired, and/or wireless coupling. Thus, coupling may be accomplishing by wiring 138 directly to wired frequency reference terminals 132, or wirelessly, to antennas included in wireless frequency reference terminals 132 on the substrates 114 or coupled to the electric energy conversion device(s) 128. In some embodiments, a system 110 may include a power bus 144 (e.g., an AC power bus) to couple to one or more electrical energy conversion devices 128. DC busses 148 may be used to couple the output of the solar energy conversion devices 120, if desired, and to transport DC current to power various devices, or to charge one or more storage batteries 152, perhaps using a charging controller CC.

The apparatus 100, systems 110, consumers 111, power grid 112, semiconductor substrates 114, solar energy conversion devices 120, electrical energy conversion devices 128, frequency reference terminals 132, wireless receiver 136, frequency reference 140, power bus 144, DC busses 148, and batteries 152 may all be characterized as “modules” herein. Such modules may include hardware circuitry, single and/or multi-processor circuits, memory circuits, software program modules and objects, and/or firmware, and combinations thereof, as desired by the architect of the apparatus 100, 104 and systems 110, 114, and as appropriate for particular implementations of various embodiments. For example, such modules may be included in a system operation simulation package, such as a software electrical signal simulation package, a power usage and distribution simulation package, a capacitance-inductance simulation package, a power/heat dissipation simulation package, a signal transmission-reception simulation package, and/or a combination of software and hardware used to operate, or simulate the operation of various potential embodiments.

It should also be understood that the apparatus and systems of various embodiments can be used in applications other than large scale solar power systems, and thus, various embodiments are not to be so limited. The illustrations of apparatus 100 and systems 110 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, single and/or multi-processor modules, single and/or multiple embedded processors, data switches, and application-specific modules, including multilayer, multi-chip modules. Such apparatus and systems may further be included as sub-components within a variety of electronic systems, such as televisions, cellular telephones, personal computers, workstations, radios, video players, vehicles, and others, such as in commercial buildings and residential buildings.

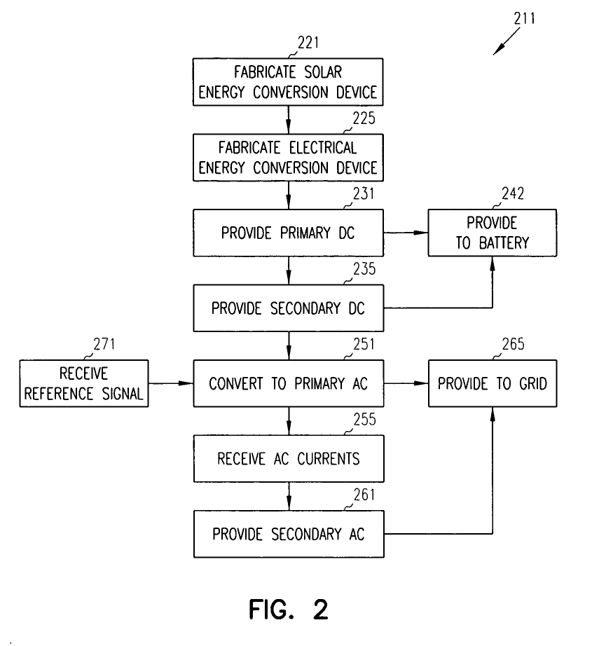

Some embodiments may include a number of methods. For example, FIG. 2 is a flow diagram illustrating several methods 211 according to various embodiments of the invention. A method 211 may begin at block 221 with fabricating one or more solar energy conversion devices on a semiconductor substrate. The method 211 may include fabricating one or more electrical energy conversion devices on the semiconductor substrate at block 225. Each electric energy conversion device may be coupled to one or more solar energy conversion devices, and each solar energy conversion device may be coupled to one or more electric energy conversion devices.

In some embodiments, the method 211 may include providing a primary direct current from one or more of the solar energy conversion devices at block 231, and providing a secondary direct current using a direct current bus, perhaps coupled to direct currents provided by one or more semiconductor substrates, each having one or more solar energy conversion devices fabricated thereon, at block 235. The primary and/or the secondary direct current may be provided to one or more storage batteries at block 241.

In some embodiments, the method 211 may include converting the primary direct current or the secondary direct current to a primary alternating current using one or more electric energy conversion devices fabricated on the semiconductor substrate at block 251. The method may continue at block 255 with receiving a plurality of alternating currents, including the primary alternating current, at an alternating current bus. The method 211 may thus include providing a secondary alternating current using an alternating current bus coupled to a plurality of semiconductor substrates having a plurality of electrical energy conversion devices at block 261.

In some embodiments, the method 211 may include providing the primary alternating current to an alternating current power grid at block 265. The method 211 may also include receiving a frequency reference signal at one or more of the electrical energy conversion devices at block 271, perhaps for synchronization with the frequency reference signal, which may be associated with a power grid frequency reference signal.

It should be noted that the methods described herein do not have to be executed in the order described, or in any particular order. Moreover, various activities described with respect to the methods identified herein can be executed in repetitive, simultaneous, serial, or parallel fashion. Information, including parameters, commands, operands, and other data, can be sent and received in the form of one or more carrier waves.

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java, Smalltalk, or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment, including Hypertext Markup Language (HTML) and Extensible Markup Language (XML). Thus, other embodiments may be realized.

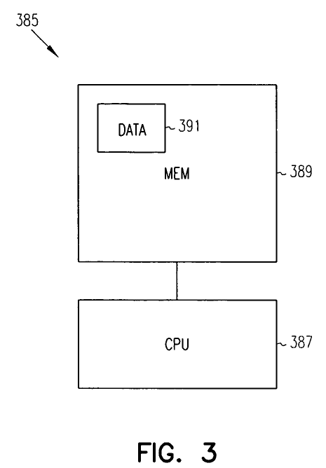

FIG. 3 is a block diagram of an article 385 according to various embodiments, such as a computer, a memory system, a magnetic or optical disk, some other storage device, and/or any type of electronic device or system. The article 385 may include a processor 387 coupled to a machine-accessible medium such as a memory 389 (e.g., a memory including an electrical, optical, or electromagnetic conductor) having associated information 391 (e.g., computer program instructions and/or data), which, when accessed, results in a machine (e.g., the processor 387) performing such actions as simulating providing direct current from a solar energy conversion device fabricated on a semiconductor substrate, and simulating converting the direct current to an alternating current using an electric energy conversion device fabricated on the semiconductor substrate. Further actions may include simulating receiving a frequency reference signal at the electrical energy conversion device, and simulating providing the alternating current to an alternating current power grid.

Implementing the apparatus, systems, and methods disclosed herein may provide grid-connected solar energy conversion systems at reduced cost, and increased reliability, since the energy conversion circuitry (e.g., an inverter) may be fabricated in the same process steps as solar energy conversion component elements. Integrated power conversion circuitry might also result in the production of lighter weight, large-scale solar panels.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. An apparatus, including:
a semiconductor substrate;
a solar energy conversion device fabricated on the semiconductor substrate; and
an electrical energy conversion device to receive electrical energy from the solar energy conversion device and fabricated on the semiconductor substrate.

2. The apparatus of claim 1, wherein the solar energy conversion device includes:
at least one solar cell.

3. The apparatus of claim 1, wherein the electrical energy conversion device includes:
a voltage step-up conversion device.

4. The apparatus of claim 1, wherein the electrical energy conversion device includes:
a direct current to alternating current conversion device.

5. The apparatus of claim 4, wherein the electrical energy conversion device includes:
a solid-state inverter.

6. The apparatus of claim 4, wherein the electrical energy conversion device includes:
an alternator.

7. The apparatus of claim 1, wherein the electrical energy conversion device includes:
a direct current to direct current conversion device.

8. The apparatus of claim 1, wherein the electrical energy conversion device includes:
a generator.

9. The apparatus of claim 1, wherein the electrical energy conversion device includes:
a flip-chip bonded to the semiconductor substrate.

10. The apparatus of claim 1, wherein the semiconductor substrate includes:
at least one of a silicon material, an arsenide material, a polymer, and an organic material.

11. The apparatus of claim 1, further including:
a frequency reference terminal to couple to the electrical energy conversion device.

12. A system, including:
a first semiconductor substrate;
a first solar energy conversion device fabricated on the first semiconductor substrate;
a first electrical energy conversion device to receive electrical energy from the first solar energy conversion device and fabricated on the first semiconductor substrate; and
a frequency reference to couple to the first electrical energy conversion device.

13. The system of claim 12, further including:
a plurality of semiconductor substrates, including the first semiconductor substrate, having a corresponding plurality of solar energy conversion devices.

14. The system of claim 12, wherein the frequency reference is coupled to the plurality of electrically coupled semiconductor substrates.

15. The system of claim 12, wherein the first electrical energy conversion device further includes:
a direct current to alternating current conversion device.

16. The system of claim 12, wherein the first electrical energy conversion device further includes:
a voltage step-up device coupled to the direct current to alternating current conversion device.

17. The system of claim 12, wherein the first semiconductor substrate includes:
at least one of a silicon material, an arsenide material, a polymer, and an organic material.

18. The system of claim 12, further including:
a second semiconductor substrate;
a second solar energy conversion device fabricated on the second semiconductor substrate;
a second electrical energy conversion device fabricated on the second semiconductor substrate;
a frequency reference terminal coupled to the frequency reference; and
a power bus to couple to the first electrical energy conversion device and to the second electrical energy conversion device.

19. A method, including:
providing a primary direct current from a first solar energy conversion device fabricated on a first semiconductor substrate; and
converting the primary direct current to a primary alternating current using a first electric energy conversion device fabricated on the first semiconductor substrate.

20. The method of claim 19, further including:
providing a secondary direct current using a direct current bus coupled to a direct current provided by a second semiconductor substrate having a second solar energy conversion device, and to the primary direct current.

21. The method of claim 19, further including:
providing a secondary alternating current using an alternating current bus coupled to an alternating current provided by a second semiconductor substrate having a second electrical energy conversion device, and to the primary alternating current.

22. The method of claim 19, further including:
fabricating the first solar energy conversion device on the first semiconductor substrate; and
fabricating the first electrical energy conversion device on the first semiconductor substrate.

23. The method of claim 19, further including:
receiving a frequency reference signal at the first electrical energy conversion device.

24. The method of claim 19, further including:
providing the primary alternating current to an alternating current power grid.

25. The method of claim 19, further including:
providing the primary direct current to at least one storage battery.

26. The method of claim 19, further including:
receiving a plurality of alternating currents, including the primary alternating current, at an alternating current bus.

27. An article including a machine-accessible medium having associated information, wherein the information, when accessed, results in a machine performing:
simulating providing a direct current from a solar energy conversion device fabricated on a semiconductor substrate; and
simulating converting the direct current to an alternating current using an electric energy conversion device fabricated on the semiconductor substrate.

28. The article of claim 27, wherein the information, when accessed, results in the machine performing:
simulating receiving a frequency reference signal at the electrical energy conversion device.

29. The article of claim 27, wherein the information, when accessed, results in the machine performing:
simulating providing the alternating current to an alternating current power grid.
